(19) United States
(12) Patent Application Publication
(10) Pub. No.: US 2012/0302038 A1
(43) Pub. Date: Nov. 29, 2012

(54) METHOD FOR PREPARING A SHALLOW TRENCH ISOLATION STRUCTURE WITH THE STRESS OF ITS ISOLATION OXIDE BEING TUNED BY ION IMPLANTATION

(75) Inventors: Chunsheng ZHENG, Shanghai (CN); Wenguang ZHANG, Shanghai (CN); Qiang XU, Shanghai (CN); Yuwen CHEN, Shanghai (CN)

(73) Assignee: SHANGHAI HUALI MICROELECTRONICS CORPORATION, Shanghai (CN)

(21) Appl. No.: 13/339,404

(22) Filed: Dec. 29, 2011

(30) Foreign Application Priority Data
May 23, 2011 (CN) 201110133619.6

(51) Int. Cl. H01L 21/302

(52) U.S. Cl. 438/433; 257/E21.214

(57) ABSTRACT

A method for preparing a shallow trench isolation structure with the stress of its isolation oxide being tuned by ion implantation comprises: step a: forming a protective layer on a semiconductor substrate; step b: forming trenches for isolating PMOS active regions and NMOS active regions on the semiconductor substrate and the protective layer; step c: forming a filling material layer in the trenches, so that the trenches are fully filled with the filling material layer to form shallow trench isolation structures. The advantageous is that, as for a device where a HARP process is applied to its shallow trench isolation, the stress in the STI can be tuned so as to be changed from tensile stress into compressive stress by performing ion implantation to the STI around the PMOS, therefore the stress state of the PMOS channel region may be changed and the performance thereof is improved.

### CROSS REFERENCE TO RELATED APPLICATIONS

The present application claims the benefit of priority, under 35 U. S. C. §119, to Chinese Application No.: CN201110133619.6 filed on May 23, 2011, the content of which is incorporated herein by reference in its entirety.

### FIELD OF THE INVENTION

The present application relates to a method for preparing a shallow trench isolation structure, and especially to a method for preparing a shallow trench isolation structure with the stress of its isolation oxide being tuned by an ion implantation.

### BACKGROUND OF THE INVENTION

Applications of sub-atmosphere chemical vapor deposition (SA-CVD) process and high density plasma chemical vapor deposition (HDP-CVD) process have been widely used in the semiconductor industry. One of the applications is Shallow Trench Isolation (STI), which is to isolate Active Areas (AA) with high-quality silicon dioxide (SiO₂). For the technology node below 90 nm, those two CVD technologies show different performances. However, SA-CVD has the advantages of excellent filling capability, tunable SiO₂ film stress and no plasma damage to the underlying material and so on, thereby being used as a preferable filling scheme for semiconductor devices in the technology node of less than 70 nm. The silicon trench aspect ratio would be continually increased as the technology node is expected to be gradually reduced, therefore the process potential of HDP-CVD of SiO₂ process cannot meet the updating requirements. People have begun to use the SA-CVD process, namely, a high aspect ratio process (HARP) of O3/TEOS chemical components with process temperature at 540° C. In STI applications, the major advantage of using HARP instead of HDP is the excellent STI filling capability with maintenance convenience and process extendibility in the technology node of 45 nm or less. The STI filled by the HARP process has a tensile stress, introducing a tensile strain in the Si channel under NMOS and a relaxed Si lattice which is preferable for electron moving, so the performance of the NMOS may be greatly enhanced. However, same scenario happens in the channel under PMOS area where the hole is the major carrier. We know a compressive strain and lattice would be good for hole moving in the channel, so a tensile strain in the PMOS channel induced by HARP STI oxide will lead to PMOS performance degrade. Thus the performance of the PMOS may be deteriorated.

Chinese patent No.: CN200710047357.5 entitled “a method for preparing trench isolation structures capable of improving performance of the semiconductor device” discloses a hybrid technical solution of void filling by means of HDP-CVD and HARP to be used in the NMOS and PMOS respectively so as to improve the performance of the devices together. However, this kind of process needs to carried out with chemical-mechanical polishing twice then with void filling twice, which is very sophisticated and may lead to lower yield rate.

### SUMMARY OF THE INVENTION

In view of the above problems, the present application provides a method for fabricating shallow trench isolation structure with the stress of its isolation oxide being tuned by an ion implantation, which may achieve the technical effects of STI stress adjustable with a simple process so as to realize the object of improving the performance of the device.

The technical means to be adopted in the present application to realize its technical object are as below.

A method for preparing a shallow trench isolation structure with the stress of its isolation oxide being tuned by an ion implantation comprises the steps of:

step a: forming a protective layer on a semiconductor substrate;

step b: forming trenches for isolating PMOS active regions and NMOS active regions on the semiconductor substrate and the protective layer;

step c: forming a filling material layer in the trenches, so that the trenches are fully filled with the filling material layer to form shallow trench isolation structures;

step d: removing excess filling materiel on the surface of the protective layer;

step e: forming a photoresist layer on the protective layer with windows formed therein, wherein the shallow trench isolation structures, except those used to isolate the NMOS active regions, are exposed by the windows formed in the photoresist layer;

step f: performing an ion implantation to the shallow trench isolation structures exposed by the windows formed at step e; and

step g: removing the photoresist layer.

In the aforementioned method for preparing a shallow trench isolation structure with the stress of its isolation oxide being tuned by an ion implantation, the semiconductor substrate is made of monocrystalline silicon.

In the aforementioned method for preparing a shallow trench isolation structure with the stress of its isolation oxide being tuned by an ion implantation, the protective layer formed at step a is a thin film of silicon nitride.

In the aforementioned method for preparing a shallow trench isolation structure with the stress of its isolation oxide being tuned by an ion implantation, the method of forming the protective layer is a chemical vapor deposition or a physical vapor deposition.

In the aforementioned method for preparing a shallow trench isolation structure with the stress of its isolation oxide being tuned by an ion implantation, the method of forming the trenches at step b comprises: forming a patterned hard mask layer over the protective layer formed at step a; and performing a dry etching by use of the patterned hard mask layer so as to form the trenches.

In the aforementioned method for preparing a shallow trench isolation structure with the stress of its isolation oxide being tuned by an ion implantation, forming the filling material layer at step c is performed by a high aspect ratio filling process.

In the aforementioned method for preparing a shallow trench isolation structure with the stress of its isolation oxide being tuned by an ion implantation, the method of removing excess filling materiel at step d is a chemical-mechanical polishing.

In the aforementioned method for preparing a shallow trench isolation structure with the stress of its isolation oxide being tuned by an ion implantation, the method of forming the photoresist layer at step e is a photoresist spin coating.

In the aforementioned method for preparing a shallow trench isolation structure with the stress of its isolation oxide being tuned by an ion implantation, the method of forming the windows in the photoresist layer at step e is a photolithography.

In the aforementioned method for preparing a shallow trench isolation structure with the stress of its isolation oxide being tuned by an ion implantation, wherein the ion implantation at step f is performed by a method of heavily doping.

In the aforementioned method for preparing a shallow trench isolation structure with the stress of its isolation oxide being tuned by an ion implantation, the ion used for performing the ion implantation at step f may be selected from argon, germanium, silicon or oxygen.

In the aforementioned method for preparing a shallow trench isolation structure with the stress of its isolation oxide being tuned by an ion implantation, the method of removing the photoresist layer at step g is a cleaning

The advantageous effects of the present application is that, as for a device where a HARP process is applied to its shallow trench isolation, the stress in the STI can be tuned so as to be changed from a tensile stress into a compressive stress by performing ion implantation to the STI around the PMOS, therefore the stress state of the PMOS channel region may be changed and the performance thereof is to be improved. The process applied herein is simple and feasible and is able to efficiently overcome the complexity of the selective filling process applied to the shallow trench.

### BRIEF DESCRIPTION OF THE DRAWING

FIG. 1 is a flow chart showing a method for preparing a shallow trench isolation structure with the stress of its isolation oxide being tuned by an ion implantation according to the present application; and

FIG. 2 is a view illustrating the state of the device structure after executing the method for preparing a shallow trench isolation structure with the stress of its isolation oxide being tuned by an ion implantation according to the present application.

### DESCRIPTION OF THE PREFERRED EMBODIMENTS

The present application will be further described in conjunction with accompanying drawings and preferred embodiments. The embodiments here are only used to illustrate but not to limit the present invention.

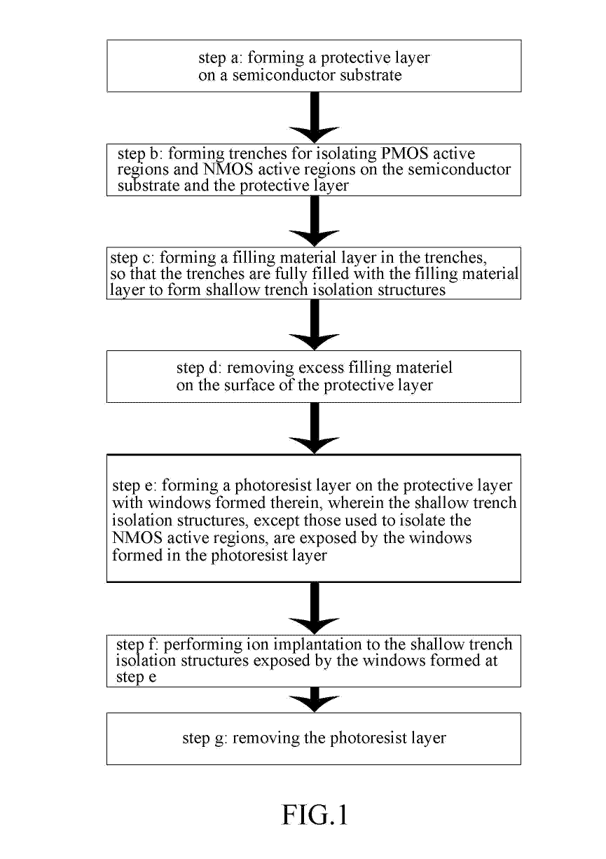

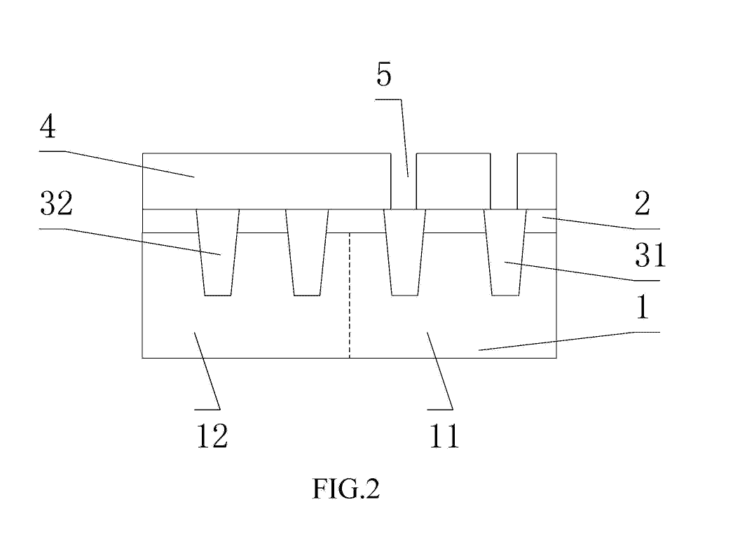

As shown in FIGS. 1 and 2, a method for preparing a shallow trench isolation structure with the stress of its isolation oxide being tuned by an ion implantation according to the present application comprises the following steps.

Step a: forming a protective layer 2 on a semiconductor substrate 1, wherein the semiconductor substrate is made of monocrystalline silicon and the protective layer 2 is a thin film of silicon nitride formed by a method of chemical vapor deposition or physical vapor deposition.

Step b: forming trenches 31 for isolating PMOS active regions 11 and trenches 32 for isolating NMOS active regions 12 on the semiconductor substrate 1 and the protective layer 2, wherein the method for forming the trenches 31 and 32 comprises, for example, firstly forming a patterned hard mask layer over the protective layer 2 formed at step a, and performing a dry etching by use of the patterned hard mask layer to form the trenches 31 and 32.

Step c: forming a filling material layer in the trenches 31 and 32, so that the trenches 31 and 32 are fully filled with the filling material layer to form shallow trench isolation structures, wherein the filling may be performed with a high aspect ratio process of sub-atmosphere chemical vapor deposition.

Step d: removing the excess filling materiel on the surface of the protective layer 2, wherein the excess filling materiel may be removed with a method of chemical-mechanical polishing.

Step e: forming a photoresist layer 4 on the protective layer 2 with windows formed therein, so as to expose the shallow trench isolation structures except those used to isolate NMOS active regions 12. The photoresist layer is formed by a photoresist spin coating, and the windows 5 are formed by a photolithography so as to expose the shallow trench isolation structures. More specifically, the shallow trench isolation structures only used to isolate the PMOS active regions 11 are all exposed by the windows 5 formed in the photoresist layer 4, while the shallow trench isolation structures used to isolate both the NMOS active regions 12 and the PMOS active regions 11, for example, the shallow trench isolation structures in the interface regions between the NMOS active regions 12 and PMOS the active regions 11, are covered by the photoresist layer 4 so as not to be exposed.

Step f: performing an ion implantation to the shallow trench isolation structures exposed by the windows 5 formed at step e, wherein the ion implantation is performed by heavily doping, and the ion used herein may be selected from argon, germanium, silicon or oxygen.

Step g: removing the photoresist layer 4 by means of cleaning

In order to enhance the effect of stress adjustment, a heat treatment may be performed subsequently.

The method for preparing a shallow trench isolation structure with the stress of its isolation oxide being tuned by an ion implantation according to the present application achieves the improvement of the performance of the NMOS by applying the HARP process. Meanwhile, by performing an ion implantation to the STI around the PMOS, the stress thereof is changed from a tensile stress into a compressive stress, so as to change the stress state of the PMOS channel region to suppress or eliminate the influence of the HARP process on the performance of the PMOS. Thereby the entire performance of the device is able to be improved. The STI structure in the interface region between the NMOS and PMOS is shared by the adjacent NMOS and PMOS, and the ion implantation is not performed to the shared STI so as not to affect the performance of the NMOS device. Although in the interface region, there is no compressive stress formed in the channel of the PMOS adjacent to the NMOS, the tensile stress brought from a side of the shared STI can be balanced by the pulling stress produced from the side of unshared STI by the ion implantation, so that the improvement to the performance of the PMOS may be significant, although the improvement may be less significant than the improvement to other regions.

The above description is only led to the preferred embodiments of the present application, which are intended to illustrate but not to limit the scope of the present application. The embodiments or embodied results thereof, which can be obtained from equivalent structural variations with the contents of the description and drawings of the present application, from substitutions by using well-known materials having equivalent functions with that of the materials mentioned in the present application, and from replacement by using well-known methods having equivalent functions with that of the methods mentioned in the present application, will all fall within the protection scope of the present application.

What is claimed is:

1. A method for preparing a shallow trench isolation structure with the stress of its isolation oxide being tuned by an ion implantation, which comprising the steps of:
step a: forming a protective layer on a semiconductor substrate;
step b: forming trenches for isolating PMOS active regions and NMOS active regions on the semiconductor substrate and the protective layer;
step c: forming a filling material layer in the trenches, so that the trenches are fully filled with the filling material layer to form shallow trench isolation structures;
step d: removing excess filling materiel on the surface of the protective layer;
step e: forming a photoresist layer on the protective layer with windows formed therein, wherein the shallow trench isolation structures, except those used to isolate the NMOS active regions, are exposed by the windows formed in the photoresist layer;
step f: performing an ion implantation to the shallow trench isolation structures exposed by the windows formed at step e; and
step g: removing the photoresist layer.

2. The method for preparing a shallow trench isolation structure with the stress of its isolation oxide being tuned by an ion implantation of claim 1, wherein the semiconductor substrate is made of monocrystalline silicon.

3. The method for preparing a shallow trench isolation structure with the stress of its isolation oxide being tuned by an ion implantation of claim 1, wherein the protective layer formed at step a is a thin film of silicon nitride.

4. The method for preparing a shallow trench isolation structure with the stress of its isolation oxide being tuned by an ion implantation of claim 1, wherein the method of forming the protective layer at step a is a chemical vapor deposition or a physical vapor deposition.

5. The method for preparing a shallow trench isolation structure with the stress of its isolation oxide being tuned by an ion implantation of claim 1, wherein the method of forming the trenches at step b comprises: forming a patterned hard mask layer over the protective layer formed at step a; and performing a dry etching by use of the patterned hard mask layer so as to form the trenches.

6. The method for preparing a shallow trench isolation structure with the stress of its isolation oxide being tuned by an ion implantation of claim 1, wherein forming the filling material layer at step c is performed by using a high aspect ratio filling process.

7. The method for preparing a shallow trench isolation structure with the stress of its isolation oxide being tuned by an ion implantation of claim 1, wherein the method of removing excess filling materiel at step d is a chemical-mechanical polishing.

8. The method for preparing a shallow trench isolation structure with the stress of its isolation oxide being tuned by an ion implantation of claim 1, wherein the method of forming the photoresist layer at step e is a photoresist spin coating.

9. The method for preparing a shallow trench isolation structure with the stress of its isolation oxide being tuned by an ion implantation of claim 1, wherein the method of forming the windows in the photoresist layer at step e is a photolithography.

10. The method for preparing a shallow trench isolation structure with the stress of its isolation oxide being tuned by an ion implantation of claim 1, wherein the ion implantation at step f is performed by heavily doping.

11. The method for preparing a shallow trench isolation structure with the stress of its isolation oxide being tuned by an ion implantation of claim 1, wherein the ion used for performing the ion implantation at step f is selected from argon, germanium, silicon or oxygen.

12. The method for preparing a shallow trench isolation structure with the stress of its isolation oxide being tuned by an ion implantation of claim 1, wherein the method of removing the photoresist layer at step g is a cleaning.
